(19) United States
(12) Patent Application Publication
(10) Pub. No.: US 2008/0068055 A1
(43) Pub. Date: Mar. 20, 2008

(54) Circuit for generating rotating electric field

(76) Inventor: Kristos Mavros, Lidcombe (AU)

Correspondence Address: STETINA BRUNDA GARRED & BRUCKER, 75 ENTERPRISE, SUITE 250, ALISO VIEJO, CA, 92656, US

(21) Appl. No.: 11/891,523

(22) Filed: Aug. 10, 2007

(30) Foreign Application Priority Data
May 23, 2006 (AU) 2006202189 B1

(51) Int. Cl. H03L 7/00

(52) U.S. Cl. 327/143

(57) ABSTRACT

A circuit for generating a rotating field using a timed power source comprising at least a first inverter and a second inverter. Also described is an assembly having plates to which the circuit is applied for the purpose of generating a rotating electric field.

### CROSS-REFERENCE TO RELATED APPLICATIONS

The present application claims priority to Australian Patent Application No. 2006202189 entitled “A circuit for generating a rotating electric field” which was filed on May 23, 2006.

### STATEMENT RE: FEDERALLY SPONSORED RESEARCH/DEVELOPMENT

Not Applicable

### BACKGROUND

A circuit and method for generating a rotating electric field wherein a pulsed power source is used to alternately charge each pair, of two diagonally opposite pairs of plates comprising a front plate, wherein the front plate is in close approximation to a back plate, so as to produce a rotating a electric field.

A number of problems have arisen in relation to the creation of electric fields using capacitors.

A first problem is that to generate a large electric field using conductive materials can involve a substantial quantity of material, which can be both expensive and costly. The generation of a rotation electric field that sweeps over a wide distance enables the use of less material and a reduction in cost, a feature that is particularly important in various industrial uses of circuits, where weight gain leads to increases in fuel costs and reduction in carriage load such as in the aircraft industry.

The second problem is the need to generate a rotating electric field in a manner that can be precisely digitally controlled. Mechanical rotation of electric charges provides a partial solution. However, digitized generation of a rotational electric field can often be produced with greater precision.

It is an object of the present invention to address or at least ameliorate some of the above disadvantages.

### BRIEF DESCRIPTION OF THE DRAWINGS

FIG. 1 is a circuit diagram showing an arrangement of pulsed power source, inverters, charging and discharging transistors, capacitors and associated components.

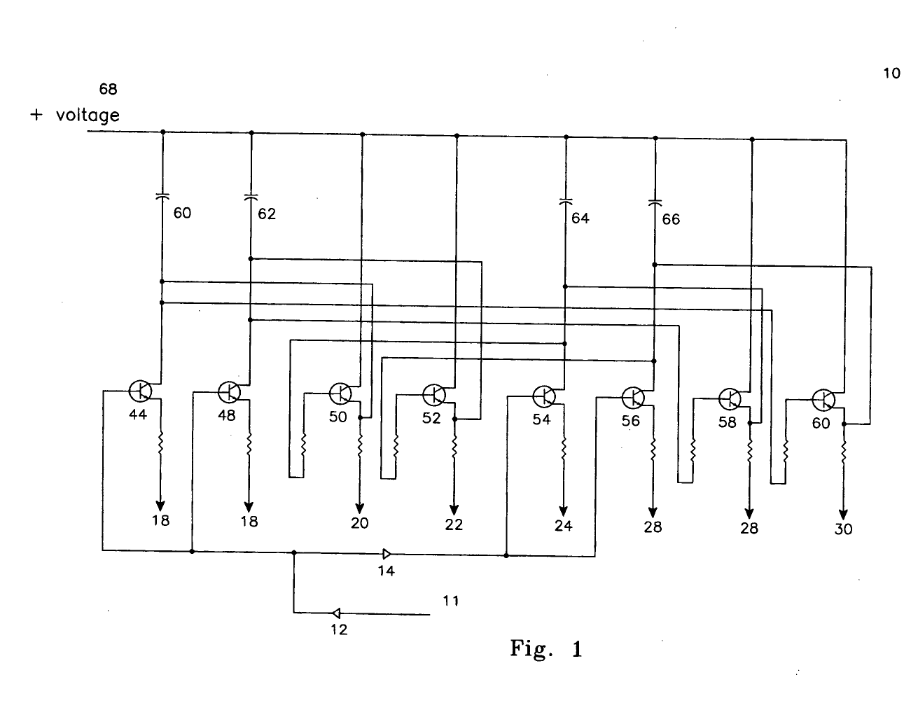

FIG. 2 shows a pair of plates comprising a front plate and a rear plate; each formed of four plates separated by insulating material.

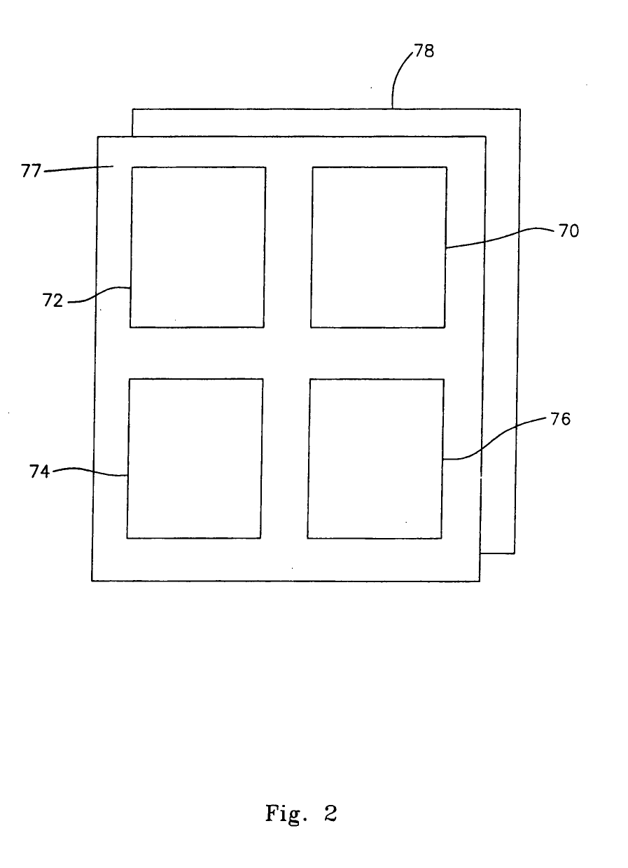

### BRIEF DESCRIPTION OF THE INVENTION

In one broad form of the invention there is provided a circuit and apparatus for generating a rotating electric field using a timed power source comprising:
a) a first inverter, a second inverter;
b) a first charging transistor, a second charging transistor, a third charging transistor, a fourth charging transistor;
c) a first discharging transistor, a second discharging transistor, a third discharging transistor, a fourth discharging transistor;
d) a first capacitor; a second capacitor; a third capacitor; a fourth capacitor;
e) a front plate located in parallel approximation to a back plate;

wherein the front plate and the back plate each include four plates of conductive material separated by an insulating material; the four plates of the back plate being of the same shape and configuration as the four plates of the front plate;

wherein when in use, the front plate and the back plate are in sufficiently close proximity so that charges on the front plate can induce reciprocal charges on the back plate;

wherein the first capacitor, the second capacitor, the third capacitor and the fourth capacitor are each respectively connected to a first conductive member, a second conductive member, a third conductive member and a fourth conductive member; the respective conductive members forming the four plates of conductive material of the front plate;

wherein the input end of the first inverter is connected in series to the timed power source;

wherein the first charging transistor, the second charging transistor and the second inverter are respectively connected in parallel to the output end of the first inverter;

wherein the third charging transistor and the fourth charging transistor are respectively connected in parallel to the output end of the second inverter;

wherein the first charging transistor, the second charging transistor, the third charging transistor and the fourth charging transistor are each respectively connected in series to the first capacitor, the second capacitor, the third capacitor and the fourth capacitor, to respectively form a first leg, a second leg, a third leg and a fourth leg;

wherein the first leg, the second leg, the third leg and the fourth leg are in parallel;

wherein the first capacitor, the second capacitor, the third capacitor and the fourth capacitor are each respectively connected in parallel to a positive voltage;

wherein the first charging transistor, the second charging transistor, the third charging transistor and the fourth charging transistor are each respectively connected in series to the first discharging transistor, the second discharging transistor, the third discharging transistor and the fourth discharging transistor;

wherein the first discharging transistor and the second discharging transistor are each respectively connected to the negative sides of the fourth capacitor and the third capacitor to form a fifth and a sixth leg respectively;

wherein the third discharging transistor and the fourth discharging transistor area each respectively connected to the negative sides of the first capacitor and the second capacitor to form a seventh and an eighth leg respectively;

whereby the first capacitor and the second capacitor are in phase when charging and discharging;

whereby third capacitor and the fourth capacitor are in phase when charging and discharging;

whereby the first capacitor and the second capacitor are both out of phase with respect to both the third capacitor and the fourth capacitor.

Preferably, each of the charging transistors and each of the discharging transistors are earthed.

Preferably, a resistor is respectively connected in series between each of the discharging transistors and an earth connection.

Preferably, a resistor is respectively connected in series between each charging transistor and each discharging transistor.

Preferably, each of the charging transistors is an NPN transistor.

Preferably, each of the discharging transistors is a PNP transistor.

Preferably, the first conductive member and the second conductive member are respectively located in diagonally opposite comers of a substantially plane surface.

Preferably, the third conductive member and fourth conductive member are respectively located in the remaining two diagonally opposite comers of the plane surface to form a front plate.

Preferably, the conductive members are each respectively insulated from one another.

Preferably, the back plate includes of a dielectric material.

Preferably, the back plate includes a conductive material.

In a further broad form of the invention, there is provided a method for generating a rotating electric field using a timed power source comprising:
a) using a first inverter, a second inverter in the circuit;
b) using a first charging transistor, a second charging transistor, a third charging transistor, a fourth charging transistor in the circuit;
c) using a first discharging transistor, a second discharging transistor, a third discharging transistor, a fourth discharging transistor;
d) using a first capacitor; a second capacitor; a third capacitor; a fourth capacitor;
e) providing a front plate located in parallel approximation to a back plate;

wherein the front plate and the back plate each include four plates of conductive material separated by an insulating material; the four plates of the back plate being of the same shape and configuration as the four plates of the front plate;

wherein when in use, the front plate and the back plate are in sufficiently close proximity so that charges on the front plate can induce reciprocal charges on the back plate;

wherein the first capacitor, the second capacitor, the third capacitor and the fourth capacitor are each respectively connected to a first conductive member, a second conductive member, a third conductive member and a fourth conductive member; the respective conductive members forming the four plates of conductive material of the front plate;

wherein the input end of the first inverter is connected in series to the timed power source;

wherein the first charging transistor, the second charging transistor and the second inverter are respectively connected in parallel to the output end of the first inverter;

wherein the third charging transistor and the fourth charging transistor are respectively connected in parallel to the output end of the second inverter;

wherein the first charging transistor, the second charging transistor, the third charging transistor and the fourth charging transistor are each respectively connected in series to the first capacitor, the second capacitor, the third capacitor and the fourth capacitor, to respectively form a first leg, a second leg, a third leg and a fourth leg;

wherein the first leg, the second leg, the third leg and the fourth leg are in parallel;

wherein the first capacitor, the second capacitor, the third capacitor and the fourth capacitor are each respectively connected in parallel to a positive voltage;

wherein the first charging transistor, the second charging transistor, the third charging transistor and the fourth charging transistor are each respectively connected in series to the first discharging transistor, the second discharging transistor, the third discharging transistor and the fourth discharging transistor;

wherein the first discharging transistor and the second discharging transistor are each respectively connected to the negative sides of the fourth capacitor and the third capacitor to form a fifth and a sixth leg respectively;

wherein the third discharging transistor and the fourth discharging transistor area each respectively connected to the negative sides of the first capacitor and the second capacitor to form a seventh and an eighth leg respectively;

whereby the first capacitor and the second capacitor are in phase when charging and discharging;

whereby third capacitor and the fourth capacitor are in phase when charging and discharging;

whereby the first capacitor and the second capacitor are both out of phase with respect to both the third capacitor and the fourth capacitor.

What is claimed is:

1. A circuit and apparatus for generating a rotating electric field using a timed power source comprising:
a) a first inverter, a second inverter;
b) a first charging transistor, a second charging transistor, a third charging transistor, a fourth charging transistor;
c) a first discharging transistor, a second discharging transistor, a third discharging transistor, a fourth discharging transistor;
d) a first capacitor; a second capacitor; a third capacitor; a fourth capacitor;
e) a front plate located in parallel approximation to a back plate;
wherein the front plate and the back plate each include four plates of conductive material separated by an insulating material; the four plates of the back plate being of the same shape and configuration as the four plates of the front plate;
wherein when in use, the front plate and the back plate are in sufficiently close proximity so that charges on the front plate can induce reciprocal charges on the back plate;
wherein the first capacitor, the second capacitor, the third capacitor and the fourth capacitor are each respectively connected to a first conductive member, a second conductive member, a third conductive member and a fourth conductive member; the respective conductive members forming the four plates of conductive material of the front plate;
wherein the input end of the first inverter is connected in series to the timed power source;
wherein the first charging transistor, the second charging transistor and the second inverter are respectively connected in parallel to the output end of the first inverter;
wherein the third charging transistor and the fourth charging transistor are respectively connected in parallel to the output end of the second inverter;
wherein the first charging transistor, the second charging transistor, the third charging transistor and the fourth charging transistor are each respectively connected in series to the first capacitor, the second capacitor, the third capacitor and the fourth capacitor, to respectively form a first leg, a second leg, a third leg and a fourth leg;
wherein the first leg, the second leg, the third leg and the fourth leg are in parallel;
wherein the first capacitor, the second capacitor, the third capacitor and the fourth capacitor are each respectively connected in parallel to a positive voltage;
wherein the first charging transistor, the second charging transistor, the third charging transistor and the fourth charging transistor are each respectively connected in series to the first discharging transistor, the second discharging transistor, the third discharging transistor and the fourth discharging transistor;
wherein the first discharging transistor and the second discharging transistor are each respectively connected to the negative sides of the fourth capacitor and the third capacitor to form a fifth and a sixth leg respectively;
wherein the third discharging transistor and the fourth discharging transistor area each respectively connected to the negative sides of the first capacitor and the second capacitor to form a seventh and an eighth leg respectively;
whereby the first capacitor and the second capacitor are in phase when charging and discharging;
whereby third capacitor and the fourth capacitor are in phase when charging and discharging;
whereby the first capacitor and the second capacitor are both out of phase with respect to both the third capacitor and the fourth capacitor.

2. The circuit according to claim 1 wherein each of the charging transistors and each of the discharging transistors are earthed.

3. The circuit according to claim 1 or claim 2 wherein a resistor is respectively connected in series between each of the discharging transistors and an earth connection.

4. The circuit according to any one of claims 1-3 wherein a resistor is respectively connected in series between each charging transistor and each discharging transistor.

5. The circuit according to any one of claims 1-4 wherein each of the charging transistors is an NPN transistor.

6. The circuit according to any one of claims 1-5 wherein each of the discharging transistors is a PNP transistor.

7. The circuit according to any one of claims 1 to 6 wherein the first conductive member and the second conductive member are respectively located in diagonally opposite comers of a substantially plane surface.

8. The circuit according to claim 7 wherein the third conductive member and fourth conductive member are respectively located in the remaining two diagonally opposite comers of the plane surface to form a front plate.

9. The circuit according to 8 wherein the conductive members are each respectively insulated from one another.

10. The circuit according to claim 9 wherein the back plate includes of a dielectric material.

11. The circuit according to claims 9 or 10 wherein the back plate includes a conductive material.

12. A method for generating a rotating electric field using a timed power source comprising:
a) using a first inverter, a second inverter in the circuit;
b) using a first charging transistor, a second charging transistor, a third charging transistor, a fourth charging transistor in the circuit;
c) using a first discharging transistor, a second discharging transistor, a third discharging transistor, a fourth discharging transistor;
d) using a first capacitor; a second capacitor; a third capacitor; a fourth capacitor;
e) providing a front plate located in parallel approximation to a back plate;
wherein the front plate and the back plate each include four plates of conductive material separated by an insulating material; the four plates of the back plate being of the same shape and configuration as the four plates of the front plate;
wherein when in use, the front plate and the back plate are in sufficiently close proximity so that charges on the front plate can induce reciprocal charges on the back plate;
wherein the first capacitor, the second capacitor, the third capacitor and the fourth capacitor are each respectively connected to a first conductive member, a second conductive member, a third conductive member and a fourth conductive member; the respective conductive members forming the four plates of conductive material of the front plate;
wherein the input end of the first inverter is connected in series to the timed power source;
wherein the first charging transistor, the second charging transistor and the second inverter are respectively connected in parallel to the output end of the first inverter;
wherein the third charging transistor and the fourth charging transistor are respectively connected in parallel to the output end of the second inverter;
wherein the first charging transistor, the second charging transistor, the third charging transistor and the fourth charging transistor are each respectively connected in series to the first capacitor, the second capacitor, the third capacitor and the fourth capacitor, to respectively form a first leg, a second leg, a third leg and a fourth leg;
wherein the first leg, the second leg, the third leg and the fourth leg are in parallel;
wherein the first capacitor, the second capacitor, the third capacitor and the fourth capacitor are each respectively connected in parallel to a positive voltage;
wherein the first charging transistor, the second charging transistor, the third charging transistor and the fourth charging transistor are each respectively connected in series to the first discharging transistor, the second discharging transistor, the third discharging transistor and the fourth discharging transistor;
wherein the first discharging transistor and the second discharging transistor are each respectively connected to the negative sides of the fourth capacitor and the third capacitor to form a fifth and a sixth leg respectively;
wherein the third discharging transistor and the fourth discharging transistor area each respectively connected to the negative sides of the first capacitor and the second capacitor to form a seventh and an eighth leg respectively;
whereby the first capacitor and the second capacitor are in phase when charging and discharging;
whereby third capacitor and the fourth capacitor are in phase when charging and discharging;
whereby the first capacitor and the second capacitor are both out of phase with respect to both the third capacitor and the fourth capacitor.

13. A method for generating a rotating electric field using the circuit according to claim 11.
